(19) United States
(12) Patent Application Publication
(10) Pub. No.: US 2011/0094778 A1
(43) Pub. Date: Apr. 28, 2011

(54) CIRCUIT BOARD AND FABRICATION METHOD THEREOF

(76) Inventors: Cheng-Po Yu, Taoyuan County (TW); Chi-Min Chang, Nantou County (TW); Wei-Ming Cheng, Kaohsiung City (TW)

(21) Appl. No.: 12/606,192

(22) Filed: Oct. 27, 2009

(51) Int. Cl. H05K 1/00; B23K 26/38

(52) U.S. Cl. 174/258; 219/121.69; 174/250; 977/773

(57) ABSTRACT

A method for fabricating a circuit board is provided. A non-conductive material layer is provided on a core substrate, wherein the non-conductive material layer comprises a dielectric material and catalytic particles. A recessed circuit structure is then formed in the non-conductive material layer with a laser beam. Simultaneously, the catalytic particles in the recessed circuit structure are activated with aid of the laser. A buried conductive structure is then formed in the recessed circuit structure by chemical copper deposition methods.

### BACKGROUND OF THE INVENTION

1. Field of the Invention

The present invention relates to a method for fabricating a high density interconnect (HDI) printed circuit board or HDI board. More particularly, the present invention relates to a method for fabricating an HDI board with a large-area copper plane utilizing laser technology.

2. Description of the Prior Art

With the development of science and technology, electronic products such as mobile phones, MP3, portable computers, consumer electronics, vehicle electronics or the related parts and equipments require even greater levels of miniaturization. To meet these requirements, the degree of circuit integration is increasing and circuit patterns are becoming much denser than ever. To accommodate these developments in the art, HDI boards have been developed.

HDI boards are defined as substrates or boards with a higher wiring density per unit area than conventional printed circuit boards (PCB). They have finer lines and spaces (<75 μm), smaller vias (<150 μm) and capture pads (<400 μm), and higher connection pad density (>20 pads/cm²) than employed in conventional PCB technology. HDI boards are used to reduce size and weight, as well as to enhance electrical performance.

A typical method of the related art for forming an HDI board includes the steps of: (1) providing a double-sided circuit board, and then forming a first resin coated copper (RCC) foil separately on two sides of the double-sided circuit board; (2) froming a number of first copper micro-vias in two copper layers of the first resin coated copper foils by using an etching process; (3) forming a second resin coated copper foil separately on each copper layer of the first resin coated copper foils; (4) forming a number of second copper micro-vias in each copper layer of the second resin coated copper foils by an etching process; (5) removing corresponding portions of the resin layer of the first and second resin coated copper foils from the first and second copper micro-via using Nd:YAG (UV) or CO₂ laser, thereby obtaining a number of stacked via-holes; and (6) electro-plating inner walls of the stacked via-holes, thereby obtaining a number of electrically conductive stacked via-holes. These electrically conductive, stacked via-holes can be used to electrically connect the first resin coated copper foils and the second resin coated copper foils.

The above-described prior art method for forming the stacked via-holes has several disadvantages. For example, the first and second copper micro-vias are formed by chemical wet etching methods. The chemical wet etching processes are complex and generally include lithographic steps such as photoresist coating, exposure, development, and then etching. Further, discrepancies may be introduced at each step. Such discrepancies may affect a size and a location of the first and second copper micro-via. Thus, such variances may occur between, e.g., the first copper micro-via and the corresponding second copper micro-via, thereby resulting in alignment or sizing errors in the finished stacked via-holes.

Therefore, it is desirable to provide an improved method for forming an HDI board that overcomes the above-described problems.

### SUMMARY OF THE INVENTION

Upon reading and understanding the present disclosure it is recognized that the inventive subject matter described herein provides novel structures and methods and may include novel structures and methods not expressed in this summary. The following summary is provided to give the reader a brief summary which is not intended to be exhaustive or limiting and the scope of the invention is provided by the attached claims and the equivalents thereof.

It is one object of the present invention to provide an improved method for forming a circuit board in order to solve the above-mentioned prior art problems and shortcomings.

One embodiment of the invention provides a method for fabricating a circuit board including: providing a substrate; forming a non-conductive material layer on the substrate, wherein the non-conductive material layer comprise a dielectric material and catalytic particles; projecting a laser beam onto the non-conductive material layer to etch at least one recessed circuit structure, and the laser beam simultaneously activating the catalytic particles in the recessed circuit structure; and forming a damascened conductive structure in the recessed circuit structure, wherein the damascened conductive structure comprises at least one fin-shaped protrusion. The dielectric material comprises epoxy resins, modified epoxy resins, polyesters, acrylate, fluoro-containing polymer, (PPO) polyphenylene oxide (PPO), polyimide, phenolic resins, polysulfone (PSF), Si-containing polymer, BT resins, polycyanate, polyethylene, polycarbonate, acrylonitrile-butadiene-styrene copolymer, polyethylene terephthalate (PET), polybutylene terephthalate (PBT), liquid crystal polymers (LCP), polyamide, PA 6, nylonpolyoxymethylene (POM)-polyphenylene sulfide (PPS), COC or a combination thereof. The catalytic particles comprise nano-particles of metal or metal coordination compound. The laser beam has a wavelength ranging between 193-10200 nm and energy of 0.1-10 mJ/cm². The laser beam has a laser spot size ranging between 30-80 μm.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-3 demonstrate a method for forming an HDI board in accordance with one embodiment of this invention.

FIG. 4 is a schematic plan view showing a method for rapidly forming a large-area copper plane in a circuit board by laser shooting technique in accordance with one embodiment of this invention.

FIG. 5 and FIG. 6 are schematic, cross-sectional views taken along line A-A′ and line B-B′ of FIG. 4 respectively.

FIG. 7 is a schematic plan view showing an exemplary method for rapidly forming a large-area copper plane in a circuit board by laser shooting technique in accordance with another embodiment of this invention.

FIG. 8 and FIG. 9 are schematic, cross-sectional views taken along line A-A′ and line B-B′ of FIG. 7 respectively.

FIG. 10 is a schematic plan view showing an exemplary method for rapidly forming a large-area copper plane in a circuit board by laser shooting technique in accordance with still another embodiment of this invention.

FIG. 11 and FIG. 12 are schematic, cross-sectional views taken along line A-A′ and line B-B′ of FIG. 10 respectively.

### DETAILED DESCRIPTION

In the following description, numerous specific details are given to provide a thorough understanding of the invention. However, it will be apparent to one skilled in the art that the invention may be practiced without these specific details. In order to avoid obscuring the present invention, some well-known system configurations and process steps are not disclosed in detail.

The present invention pertains to a method for fabricating an HDI printed circuit board or HDI board, and may be applicable to the fabrication of molded interconnect devices or may be applicable to the fabrication of package substrates. In particular, the present invention is suited for the fabrication of HDI printed circuit boards with a large-area copper plane that may be function as a ground plane or power plane of the HDI board. In a best mode, the present invention involves the use of hole-forming technique by laser shooting to form the large-area copper plane.

FIGS. 1-3 demonstrate a method for forming a circuit board 100 such as a HDI board in accordance with one embodiment of this invention. As shown in FIG. 1, a substrate 101 is provided. The substrate 101 may be a multi-layer wiring board core with multiple inner conductive traces fabricated within the substrate 101, which, for the sake of simplicity, are not shown in figures. On the top surface of the substrate 101, a patterned copper layer 110 is provided. It is understood that the substrate 101 may have a patterned copper layer on the other side of the substrate 101 although only single side of the substrate 101 is shown. Those versed in the art should understand that the present invention is applicable to double-sided printed circuit boards.

A non-conductive material layer 120 is provided on the substrate 101 to cover the patterned copper layer 110 and the exposed areas of the top surface of the substrate 101. The non-conductive material layer 120 may comprise dielectric matrix and catalytic particles dispersed or mixed in the dielectric matrix. The aforesaid catalytic particles may be activated by laser energy and a conductive layer may be selectively deposited on the laser-activated traces on the non-conductive material layer 120.

The aforesaid dielectric matrix may include but not limited to, for example, epoxy resins, modified epoxy resins, polyesters, acrylate, fluoro-containing polymer, polyphenylene oxide (PPO), polyimide, phenolic resins, polysulfone (PSF), Si-containing polymers, BT resins, polycyanate, polyethylene, polycarbonate, acrylonitrile-butadiene-styrene copolymer, polyethylene terephthalate (PET), polybutylene terephthalate (PBT), liquid crystal polymers (LCP), polyamide, PA 6, nylonpolyoxymethylene (POM)-polyphenylene sulfide (PPS), COC or a combination thereof.

The catalytic particles described above may be nano-particles of metals or metal coordination compounds. For example, suitable metal coordination compounds may include metal oxides, metal nitrides, metal complexes and/or metal chelating compounds. In one embodiment of the present invention, the aforesaid metal may include but not limited to zinc, copper, silver, gold, nickel, palladium, platinum, cobalt, rhodium, iridium, indium, iron, manganese, aluminum, chromium, tungsten, vanadium, tantalum, and/or titanium.

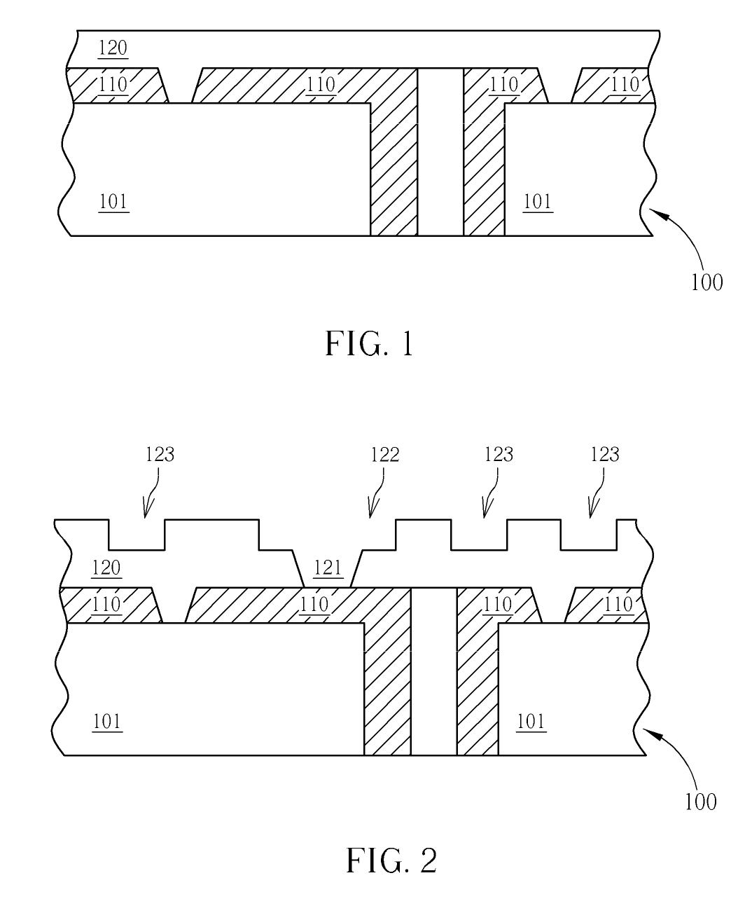

As shown in FIG. 2, a specific laser beam is directed to the top surface of the non-conductive material layer 120 to etch circuit structures such as blind via 121, solder pad opening 122 and trace trenches 123 into the non-conductive material layer 120. The blind via 121 exposes a portion of the patterned copper layer 110. Optionally, a desmear process may be carried out to ensure removal of epoxy-smear or residuals from the exposed surface of the patterned copper layer 110. Suitable desmear process may include but not limited to plasma or oxidation methods. For example, permanganate may be used as an oxidant in the desmear process.

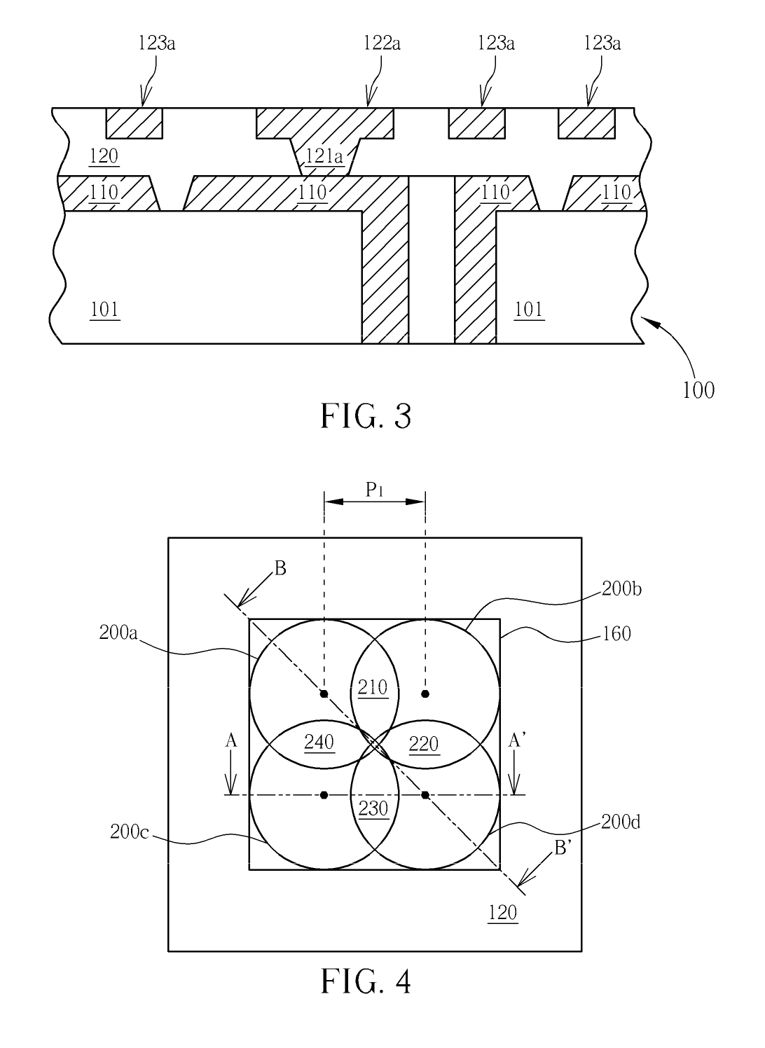

Subsequently, as shown in FIG. 3, conductive features 121a, 122a and 123a are filled into the blind via 121, solder pad opening 122 and trace trenches 123 respectively. Since the catalytic particles within the blind via 121, solder pad opening 122 and trace trenches 123 have been activated by laser, the conductive features 121a, 122a and 123a can be selectively formed in the blind via 121, solder pad opening 122 and trace trenches 123 respectively by conventional chemical copper platting or depositing methods.

In some cases, a large-area copper plane is required in the circuit board 100 to function, for example, as a ground plane or power plane of the circuit board. However, it is time-consuming to form the large-area copper plane by the laser ablation method because the laser beam with specific energy and wavelength is directed on the circuit board in a scan-and-step manner with a very tight pitch to form the circuit structures such as blind via 121, solder pad opening 122 and trace trenches 123. Therefore, the production throughput can be significantly reduced when manufacturing such circuit boards with large-area copper planes. The invention addresses this issue in one aspect.

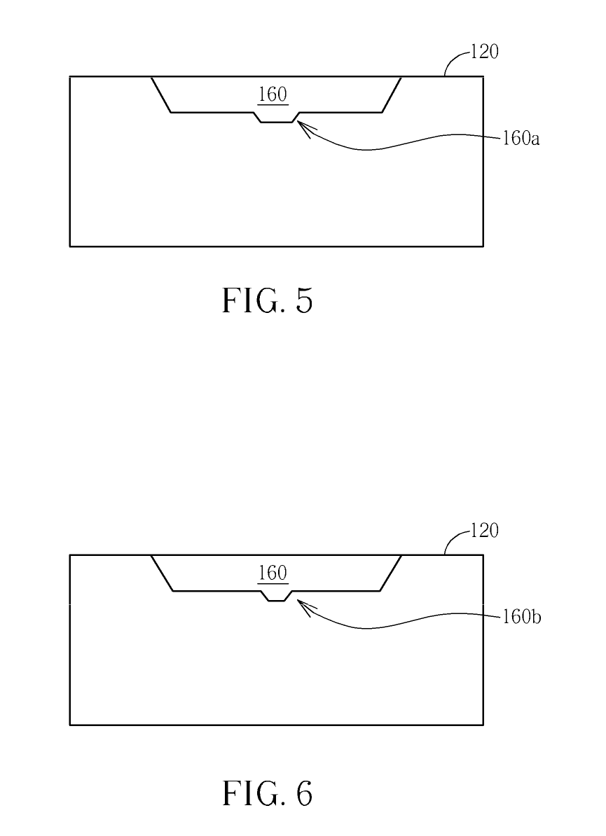

Please refer to FIGS. 4-6. FIG. 4 is a schematic plan view showing a method for rapidly forming a large-area copper plane in a circuit board by laser shooting technique in accordance with one embodiment of this invention. FIG. 5 and FIG. 6 are schematic, cross-sectional views taken along line A-A′ and line B-B′ of FIG. 4 respectively. As shown in FIG. 4, to form a large-area copper plane 160, which may function as a ground plane, a power plane or a heat-dissipating layer, on the non-conductive material layer 120 of the circuit board 100, a laser beam such as laser having an energy of about 0.1-10 mJ/cm² and a wavelength of about 193-10200 nm, preferably UV laser having an energy of about 0.6-2.0 ml/cm² and a wavelength of about 355 nm, is directed onto the non-conductive material layer 120. The laser shoots the top surface of the non-conductive material layer 120 with a laser beam spot size ranging between 30-80 μm and a laser spot pitch P₁ to form the recessed, reticular or honeycomb-like pattern on the non-conductive material layer 120.

By way of example, the laser spot 200a projected onto the non-conductive material layer 120 overlaps with the laser spots 200b and 200c, resulting in the overlapping area 210 between the laser spots 200a and 200b and the overlapping area 240 between the laser spots 200a and 200c. Likewise, the laser spot 200b overlaps with the laser spots 200a and 200d, resulting in the overlapping area 210 between the laser spots 200a and 200b and the overlapping area 220 between the laser spots 200b and 200d, while the laser spot 200d overlaps with the laser spots 200b and 200c, resulting in the overlapping area 220 between the laser spots 200b and 200d and the overlapping area 230 between the laser spots 200c and 200d. According to the embodiment of this invention, the laser spot 200a also overlaps with the laser spot 200d and the laser spot 200b overlaps with the laser spot 200c. According to the embodiment of this invention, the laser spot pitch P₁ may range between 15-80 μm.

As shown in FIG. 5 and FIG. 6, which are schematic, cross-sectional views taken along line A-A′ and line B-B′ of FIG. 4 respectively, after the metal such as copper is filled into the recessed, reticular pattern formed by the above-described laser shooting method, a damascened, large-area copper plane 160 is formed. According to the invention method for rapidly forming a large-area copper plane by laser shooting technique, after the metal filling, fin-shaped protrusions 160a and 160b are formed in the overlapping areas between the laser spots. It is advantageous to use the invention because in some cases the large-area copper plane 160 may also function as a heat-dissipating layer and these fin-shaped protrusions 160a and 160b provide increased surface area for dissipating heat and thus enhance the heat dissipation efficiency of the circuit board.

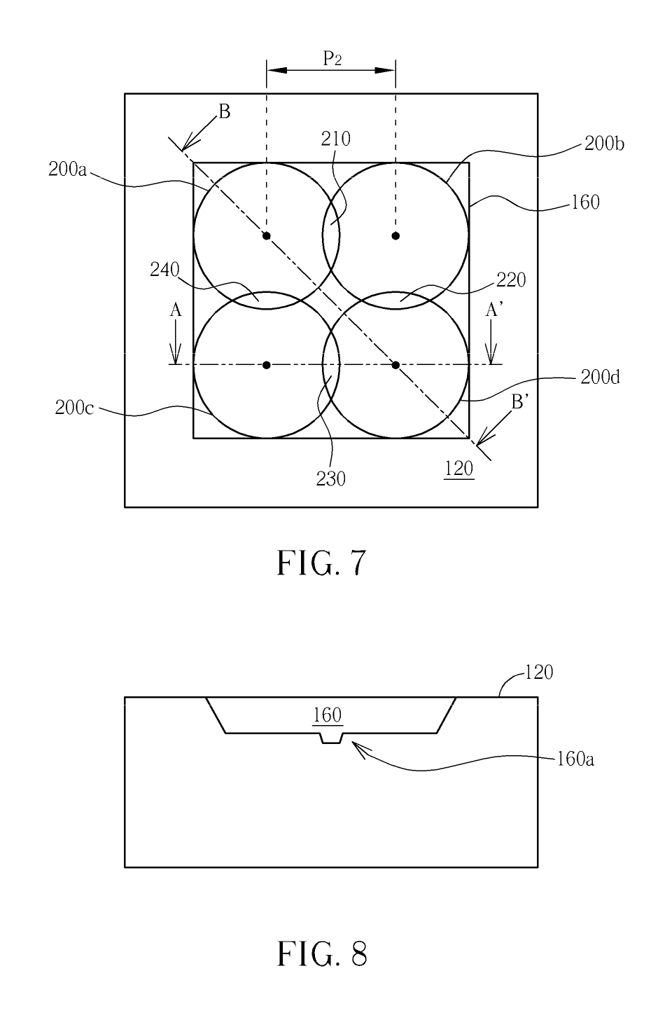

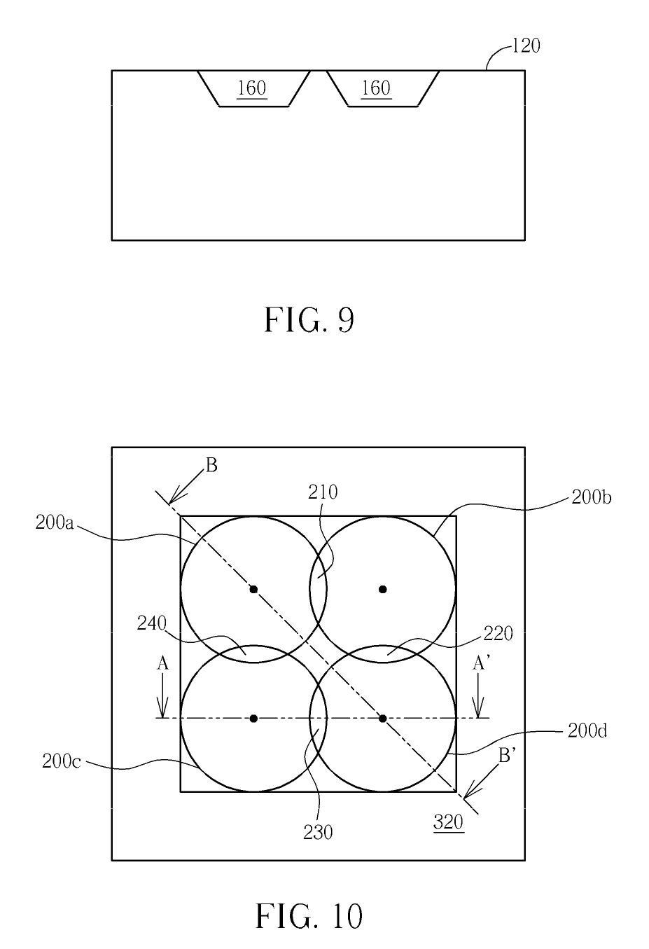

Please refer to FIGS. 7-9. FIG. 7 is a schematic plan view showing an exemplary method for rapidly forming a large-area copper plane in a circuit board by laser shooting technique in accordance with another embodiment of this invention. FIG. 8 and FIG. 9 are schematic, cross-sectional views taken along line A-A′ and line B-B′ of FIG. 7 respectively. As shown in FIG. 7, likewise, to form a large-area copper plane 160 on the non-conductive material layer 120 of the circuit board 100, a laser beam such as laser having an energy of about 0.1-10 mu/cm² and a wavelength of about 193-10200 nm, preferably UV laser having an energy of about 0.6 mJ/cm² and a wavelength of about 355 nm, is directed onto the non-conductive material layer 120. The laser shoots the top surface of the non-conductive material layer 120 with a laser beam spot size ranging between 30-80 μm and a laser spot pitch P₂ that is larger than P₁ to form the recessed reticular pattern on the non-conductive material layer 120.

For example, the laser spot 200a projected onto the non-conductive material layer 120 overlaps with the laser spots 200b and 200c, resulting in the overlapping area 210 between the laser spots 200a and 200b and the overlapping area 240 between the laser spots 200a and 200c. Likewise, the laser spot 200b overlaps with the laser spots 200a and 200d, resulting in the overlapping area 210 between the laser spots 200a and 200b and the overlapping area 220 between the laser spots 200b and 200d, while the laser spot 200d overlaps with the laser spots 200b and 200c, resulting in the overlapping area 220 between the laser spots 200b and 200d and the overlapping area 230 between the laser spots 200c and 200d. According to the embodiment of this invention, with the larger laser spot pitch P₂, the laser spot 200a does not overlap with the laser spot 200d and the laser spot 200b does not overlap with the laser spot 200c. According to the embodiment of this invention, the laser spot pitch P₂ may range between 15-80 μm.

As shown in FIG. 8 and FIG. 9, which are schematic, cross-sectional views taken along line A-A′ and line B-B′ of FIG. 7 respectively, after the metal such as copper is filled into the recessed reticular pattern formed by the above-described laser shooting method, a damascened, large-area copper plane 160 is formed. According to the invention method for rapidly forming a large-area copper plane by laser shooting technique, after the metal filling, the fin-shaped protrusions are formed in the overlapping areas 210, 220, 230, 240 between the laser spots, for example, the fin-shaped protrusion 160a in the overlapping area 230. Since the laser spot 200a does not overlap with the laser spot 200d, discontinuity, which is formed of the non-conductive material layer 120 between the laser spot 200a and the laser spot 200d, is formed in the large-area copper plane 160. Since the larger laser spot pitch P₂ is used, the throughput can be improved. The fin-shaped protrusion 160a provides increased surface area for dissipating heat and thus enhance the heat dissipation efficiency of the circuit board.

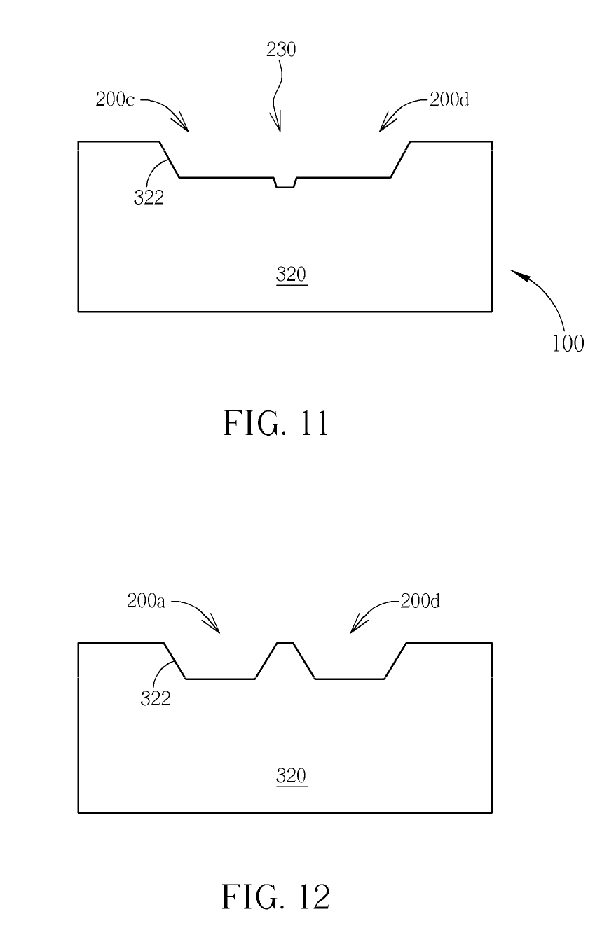

Please refer to FIGS. 10-12. FIG. 10 is a schematic plan view showing an exemplary method for rapidly forming a large-area copper plane in a circuit board by laser shooting technique in accordance with still another embodiment of this invention. FIG. 11 and FIG. 12 are schematic, cross-sectional views taken along line A-A′ and line B-B′ of FIG. 10 respectively. As shown in FIG. 10, likewise, to form a large-area copper plane on the non-conductive material layer 320 of the circuit board 100, a laser beam such as laser having an energy of about 0.1-10 mJ/cm² and a wavelength of about 193-10200 nm, preferably UV laser having an energy of about 0.6 mJ/cm² and a wavelength of about 355 nm, is directed onto the non-conductive material layer 320. The laser shoots the top surface of the non-conductive material layer 320 with a laser beam spot size ranging between 30-80 μm to form the recessed, reticular pattern 322 on the non-conductive material layer 320. According to the embodiment of this invention, the non-conductive material layer 320 does not contain the catalytic particles as described above.

For example, the laser spot 200a projected onto the non-conductive material layer 320 overlaps with the laser spots 200b and 200c, resulting in the overlapping area 210 between the laser spots 200a and 200b and the overlapping area 240 between the laser spots 200a and 200c. Likewise, the laser spot 200b overlaps with the laser spots 200a and 200d, resulting in the overlapping area 210 between the laser spots 200a and 200b and the overlapping area 220 between the laser spots 200b and 200d, while the laser spot 200d overlaps with the laser spots 200b and 200c, resulting in the overlapping area 220 between the laser spots 200b and 200d and the overlapping area 230 between the laser spots 200c and 200d.

After the formation of the recessed, reticular pattern 322 on the non-conductive material layer 320 by the laser shooting method, a metal layer is then deposited into the recessed, reticular pattern 322 so as to form a large-area copper plane on the non-conductive material layer 320. According to the embodiment of this invention, the metal layer may be deposited by conventional plating techniques.

Those skilled in the art will readily observe that numerous modifications and alterations of the device and method may be made while retaining the teachings of the invention.

What is claimed is:

1. A method for fabricating a circuit board, comprising:
providing a substrate;
forming a non-conductive material layer on the substrate, wherein the non-conductive material layer comprise a dielectric material and catalytic particles;
projecting a laser beam onto the non-conductive material layer to etch at least one recessed circuit structure, and the laser beam simultaneously activating the catalytic particles in the recessed circuit structure; and
forming a damascened conductive structure in the recessed circuit structure, wherein the damascened conductive structure comprises at least one fin-shaped protrusion.

2. The method for fabricating a circuit board according to claim 1, wherein the catalytic particles comprise nano-particles of metal or metal coordination compound.

3. The method for fabricating a circuit board according to claim 1, wherein the laser beam has a laser spot size ranging between 30-80 μm.

4. The method for fabricating a circuit board according to claim 1, wherein the laser beam has a laser spot pitch ranging between 15-80 μm.

5. A method for fabricating a circuit board, comprising:
providing a substrate;
forming a non-conductive material layer on the substrate, wherein the non-conductive material layer comprise a dielectric material and catalytic particles;
projecting a laser beam onto the non-conductive material layer to etch a recessed reticular pattern into the non-conductive material layer, and the laser beam simultaneously activating the catalytic particles in the recessed reticular pattern; and
forming a damascened conductive structure in the recessed reticular pattern, wherein the damascened conductive structure comprises at least one fin-shaped protrusion.

6. The method for fabricating a circuit board according to claim 5, wherein the dielectric material comprises epoxy resins, modified epoxy resins, polyesters, acrylate, fluoro-containing polymer, polyphenylene oxide (PPO), polyimide, phenolic resins, polysulfone (PSF), Si-containing polymers, BT resins, polycyanate, polyethylene, polycarbonate, acrylonitrile-butadiene-styrene copolymer, polyethylene terephthalate (PET), polybutylene terephthalate (PBT), liquid crystal polymers (LCP), polyamide, PA 6, nylonpolyoxymethylene (POM) polyphenylene sulfide (PPS), COC or a combination thereof.

7. The method for fabricating a circuit board according to claim 5, wherein the catalytic particles comprise nano-particles of metal or metal coordination compound.

8. The method for fabricating a circuit board according to claim 5, wherein the laser beam has a laser spot size ranging between 30-80 μm.

9. The method for fabricating a circuit board according to claim 5, wherein the laser beam has a laser spot pitch ranging between 15-80 μm.

10. A circuit board, comprising:
a substrate;
a non-conductive material layer on the substrate, wherein the non-conductive material layer comprise a dielectric material and catalytic particles;
a recessed reticular pattern in the non-conductive material layer, wherein the recessed reticular pattern is formed by projecting a laser beam onto the non-conductive material layer; and
a damascened conductive structure in the recessed reticular pattern, wherein the damascened conductive structure comprises at least one fin-shaped protrusion.

11. The circuit board according to claim 10, wherein the dielectric material comprises epoxy resins, modified epoxy resins, polyesters, acrylate, fluoro-containing polymer, polyphenylene oxide (PPO), polyimide, phenolic resins, polysulfone (PSF), Si-containing polymers, BT resins, polycyanate, polyethylene, polycarbonate, acrylonitrile-butadiene-styrene copolymer, polyethylene terephthalate (PET), polybutylene terephthalate (PBT), liquid crystal polymers (LCP), polyamide, PA 6, nylonpolyoxymethylene (POM)-polyphenylene sulfide (PPS), COC or a combination thereof.

12. The circuit board according to claim 10, wherein the catalytic particles comprise nano-particles of metal or metal coordination compound.

13. The circuit board according to claim 10, wherein the laser beam has a laser spot size ranging between 30-80 μm.

14. The circuit board according to claim 10, wherein the laser beam has a laser spot pitch ranging between 15-80 μm.

15. A method for fabricating a circuit board, comprising:
providing a substrate;
forming a non-conductive material layer on the substrate;
projecting a laser beam onto the non-conductive material layer to etch at least one recessed circuit structure therein; and
forming a damascened conductive structure in the recessed circuit structure, wherein the damascened conductive structure comprises at least one fin-shaped protrusion.

16. The method for fabricating a circuit board according to claim 15, wherein the laser beam has a laser spot size ranging between 30-80 μm.

17. The method for fabricating a circuit board according to claim 15, wherein the laser beam has a laser spot pitch ranging between 15-80 μm.

18. A circuit board, comprising:
a substrate;
a non-conductive material layer on the substrate;
a recessed reticular pattern in the non-conductive material layer, wherein the recessed reticular pattern is formed by projecting a laser beam onto the non-conductive material layer; and
a damascened conductive structure in the recessed reticular pattern, wherein the damascened conductive structure comprises at least one fin-shaped protrusion.

19. The circuit board according to claim 18, wherein the laser beam has a laser spot size ranging between 30-80 μm.

20. The circuit board according to claim 18, wherein the laser beam has a laser spot pitch ranging between 15-80 μm.
